(19) United States
(12) Patent Application Publication
(10) Pub. No.: US 2023/0333031 A1
(43) Pub. Date: Oct. 19, 2023

(54) SAMPLE BLOCK AND SAMPLE BLOCK HOLDER

(71) Applicant: ROCKTYPE LTD, Oxford Oxfordshire (GB)

(72) Inventor: Henrik Nilsen OMMA, Oxford Oxfordshire (GB)

(21) Appl. No.: 18/008,071

(22) PCT Filed: Jun. 2, 2021
(86) PCT No.: PCT/GB2021/051364

§ 371 Date: Dec. 2, 2022

(30) Foreign Application Priority Data
Jun. 3, 2020 (GB) 2008360.6

(51) Int. Cl. G01N 23/2202; G01N 23/2251

(52) U.S. Cl. CPC G01N 23/2202; G01N 23/2251; G01N 2223/418

(57) ABSTRACT

A sample block (1) and a sample block holder (51) for use in the analysis of material samples, such as rock drill cuttings (24), using a scanning electron microscope. The sample block (1) is provided with a profile that facilitates alignment within the sample block holder (51) that ensures that a sample block (1) that is inspected and then subsequently re-inspected remains in the same orientation for the first and second inspections. Areas of interest of the rock drill cuttings (24) identified in the first inspection can thus be reliably inspected during the second inspection because the possibility of the sample block (1) being submitted in a different orientation has been removed.

Scanning electron microscopes are used for material analysis in a number of different industries and technical fields. The analysis may be conducted on manufactured components, such as aerospace components, to ensure that they are of sufficient quality, or the analysis may be undertaken on geological samples. Analysis of raw geological samples is undertaken to obtain petrographic data, such as information on the mineral content of the rock. The petrographic data is obtained by analysing a sample block, also known as a ‘puck’, which is a geological sample encased in a fixing medium, for example an epoxy resin. The sample encased within the fixing medium might be for example a ‘whole rock’ sample, such as a core or outcrop rock sample, or the sample might be a particle sample, such as drill cuttings, or sand.

A typical technique for manufacturing a puck is to place a sample of washed, dried and sieved drill cuttings into a cylindrical mould and to fill that mould with epoxy resin (e.g. Struers low-viscosity EpoFix resin). The resin is forced into the sample under high pressure, or under a vacuum, in order that any pore spaces between the drill cuttings are filled with resin so that they can be detected during subsequent analysis. The resin is then cured, the cured puck is cut, or ground, to expose the desired material surface and the material surface is polished to a high degree, for example to a ‘micron smooth surface’. Pucks can be analysed by using an automated petrography system based around a scanning electron microscope. One such system is the Quantitative Evaluation of Materials by Scanning Electron Microscopy, or QEMSCAN®. If the puck is to be analysed by using a scanning electron microscope then, in addition to the previously described steps, a carbon coating is applied to the polished material surface.

Pucks can be analysed by different techniques. To provide one example of how a puck may be used in an analysis technique the QEMSCAN® process will now be described.

A cylindrical puck is loaded into a puck holder such that the material surface is visible. The puck holder constrains the puck from translational motion within the holder along any of the X, Y or Z axes, but the puck can rotate within the holder because the puck is cylindrical. The puck's freedom to rotate within the puck holder means that there is often a need to record an initial position of the puck relative to the puck holder. A technique for recording the initial position of the puck is to score the puck with an orientation line. In the process of loading the puck into the puck holder the orientation line is aligned with a corresponding orientation mark on the puck holder. The puck holder and the puck are loaded into the scanning electron microscope and the scanning is commenced. A single square portion of the puck is scanned, for example a 14 mm×14 mm area, or an 18 mm×18 mm area. The rest of the puck is not scanned. The scanning is undertaken using a field grid and the electron beam is moved across the material surface in an X and in a Y direction thereby collecting data at spaced apart points. An initial scan is undertaken at a ‘low resolution’ and can be completed relatively quickly. The puck holder and the puck are removed from the scanning electron microscope. The puck is removed from the puck holder and is stored for possible future use. The results of the scan are then ready for analysis.

If the analysis identifies an area of the material surface that is of interest and for which further information is needed, then the puck can be re-submitted to the QEMSCAN process for a detail scan at a ‘high resolution’. The puck is loaded once more into the puck holder, with the orientation line on the puck aligned with the orientation mark on the puck holder to ensure that the orientation of the puck for the detailed scan is the same as for the initial scan. The puck holder is placed in the scanning electron microscope and the scanning electron microscope is directed to the area of the material surface for which the additional information is needed (using the field grid that was utilised during the initial scan). It is desirable to scan only the area of interest of the material surface, because high resolution scanning is slow and thus, to optimise the efficiency of the process, it is necessary to scan no more of the material surface that necessary. The specific area of the material surface is scanned at high resolution and then the puck holder and puck are removed from the scanning electron microscope, the puck is stored and the data is sent for analysis.

This configuration of the current equipment has an inherent weakness, because it is possible to change the position of a puck between the initial scan and the detail scan. This may occur in various ways, for example through a failure to provide an orientation line on the puck, a failure to properly align the orientation line with the orientation mark on the puck holder, or a mistaken identification of an orientation line. There is therefore a desired for an improved set of equipment that overcomes this weakness.

In order to improve the efficiency of administration of the QEMSCAN® process, a puck holder can be provided that has the capability of holding multiple pucks. The shape and configuration of a multiple puck holder is standardised within the rock sample analysis industry, in order to increase the ease with which equipment from different manufacturers can be integrated into a laboratory testing environment. A typical multiple puck holder has the capability of holding six pucks, in a rectangular array of two columns and three rows.

Accordingly, the present invention provides a sample block that comprises a planar material inspection surface and a body extending away from the material inspection surface in a direction perpendicular to the planar material inspection surface, the external perimeter of the sample block in a plane parallel to the material inspection surface is defined in part by a circle located within plane and that surrounds the sample block, wherein the external perimeter of the sample block extends to the circumference of the circle and touches it at a first contact point on the circle and wherein there is a second contact point on the circle that is diametrically opposite to the first contact point and wherein the external perimeter of the sample block extends to the circumference of the circle (C) and touches it at the second contact point, the sample block comprising a first orientation feature forming part of the external perimeter of the sample block in the plane, the orientation feature extending at least part way through the height of the body, wherein there is a rotation point on the sample block that is located midway along a line drawn between the first contact point and the second contact point and wherein the sample block is asymmetrical when rotated in the plane about the rotation point. This configuration of the sample block, or puck, is advantageous because it permits the puck to be used with existing sample preparation and sample analysis equipment, such as polishers and holders for scanning electron microscopes, and also because it ensures that the puck can only be placed in a puck holder in one orientation. This means that if a puck needs to be subjected to a further scan after an initial scan has been carried out then it is automatically the case that the puck is oriented in the same way for the second scan as it was for the first. This avoids the possibility of the second scan looking at the wrong part of the sample.

Preferably the sample block further comprises a second orientation feature extending at least part way through the height of the body, wherein the first and second orientation features have complementary shapes, such that, in use, the second orientation feature of one of two sample blocks can be located at least partially within the first orientation feature of the other of the two sample blocks, or the first orientation feature of one of two sample blocks can be located at least partially within the second orientation feature of the other of the two sample blocks. The provision of complementarily shaped orientation features means that sample blocks can be arranged in an array in an efficient manner, i.e. with a minimum of wasted area. This can increase the speed of processing of samples because it allows more to be loaded into a scanning electron microscope at any one time.

Preferably the first and second orientation features are opposite each other. Location of the orientation surfaces opposite to each other facilitates close packing of sample blocks, whether in a sample block holder, or whether in a storage or transport tray.

Preferably the body of the sample block is defined by the material inspection surface, by a back surface that is perpendicularly spaced apart from the material inspection surface, by a forward orientation surface comprising the first orientation feature and by a rearward orientation surface comprising the second orientation feature, wherein the forward and rearward orientation surfaces are located opposite each other.

The sample block may further comprise a first side surface and a second side surface, wherein the first and second side surfaces are parallel to each other and are each connected at one end to the forward orientation surface and at the other end to the rearward orientation surface. Parallel first and second side surfaces assists with location of the sample blocks in a sample block holder and allows close packing of sample blocks.

Preferably the first orientation feature is a forward orientation surface which has a convex curved section with a radius of curvature that matches the radius of the circle, and where in the second orientation feature is a rearward orientation surface, which has a concave curved section with a radius of curvature that matches the radius of the circle. This arrangement results in the surface areas of the forward orientation surface and the rearward orientation surface being relatively large. The consequence of providing relatively large areas is that those areas are less susceptible to wear when the sample block is being polished, being held in the sample block holder during inspection or being stored. This is advantageous because the external dimensions of the sample blocks can be kept largely to the manufactured dimensions, such that the sample blocks remain a close fit within the recesses of the sample block tray which reduces an errors that may occur if a sample block needs to be re-inspected, e.g. if a sample block needs to be subjected to a detailed analysis after a preliminary analysis has been conducted.

Preferably, in the plane, the concave curved section of the rearward orientation surface further comprises at each of its ends a corner surface and wherein the corner surfaces have a convex curve with a radius of curvature that matches the radius of the circle. The provision of convex surfaces on the corner surfaces provides the same advantage as provided by the front and rear orientation surfaces, i.e. it reduces the wear on the sample block during use.

According to the first aspect of the present invention there is provided a sample block tray for use with sample blocks according to any one of the preceding claims having a surface that is provided with a plurality of sample block recesses wherein the sample block recesses are arranged in an array of rows and columns and wherein within a column each of the sample block recesses in that column is at least partially open to an adjacent sample block recess, wherein abutments are provided between rows of sample block recesses, wherein a window is associated with each of the sample block recesses, wherein the sample block recesses are arranged at least in a forward row and in a rearward row and in a first column and in a second column, wherein the sample block recesses in the forward row are provided at their forward end with a concave restraining wall that has a circular curvature and that is complementary to the orientation feature of a sample block and at their rearward end with an abutment at each corner and wherein the sample block recesses in the rearward row are provided at their forward end with an abutment at each corner and at their rearward end with a convex restraining wall that has a circular curvature.

According to a second aspect of the present invention there is provided a sample block tray having a surface that is provided with a plurality of sample block recesses wherein the sample block recesses are arranged in an array of rows and columns and wherein within a column each of the sample block recesses in that column is at least partially open to an adjacent sample block recess, wherein abutments are provided between rows of sample block recesses and wherein a window is associated with each of the sample block recesses. This arrangement of recesses permits an efficient use of space within the sample block tray thus allowing the maximum number of sample blocks to be held within it.

Preferably the sample block tray has sample block recesses that are arranged at least in a forward row and in a rearward row and in a first column and in a second column, wherein the sample block recesses in the forward row are provided at their forward end with a concave restraining wall that has a circular curvature and at their rearward end with an abutment at each corner and wherein the sample block recesses in the rearward row are provided at their forward end with an abutment at each corner and at their rearward end with a convex restraining wall that has a circular curvature.

The present invention will be described with reference to the following figures:

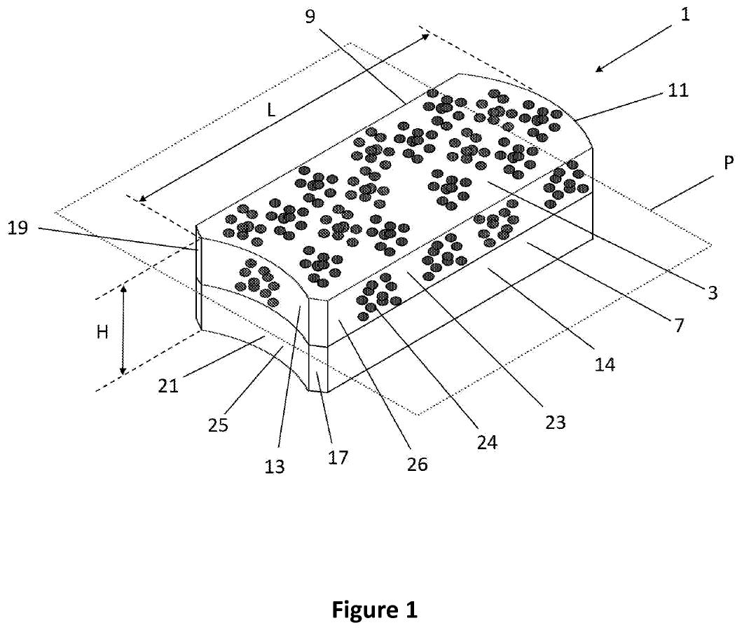

FIG. 1 is a plan view of a puck, or sample block, according to a first aspect of the present invention;

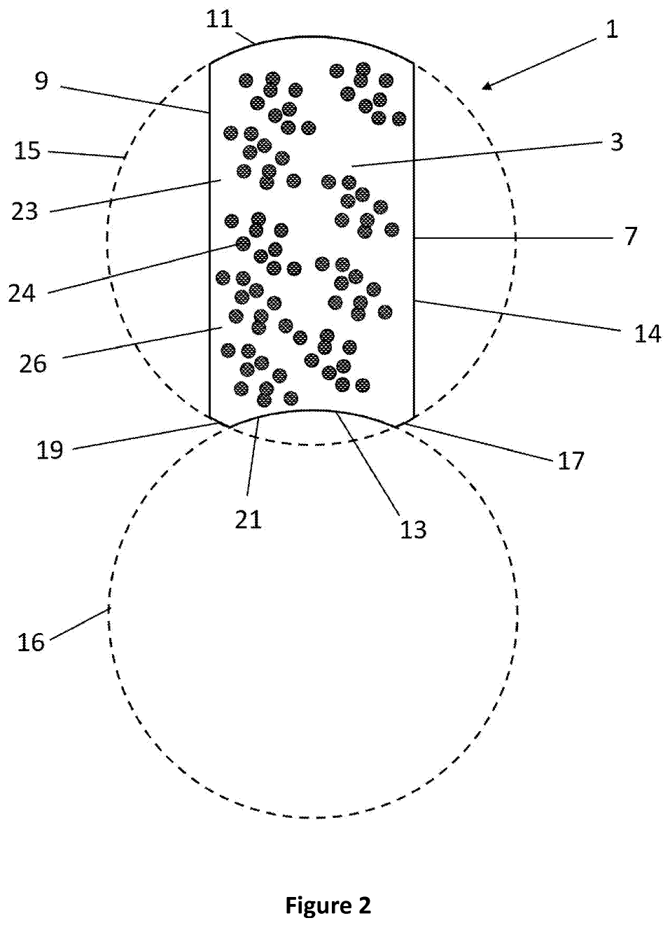

FIG. 2 is a perspective view of the puck of FIG. 1;

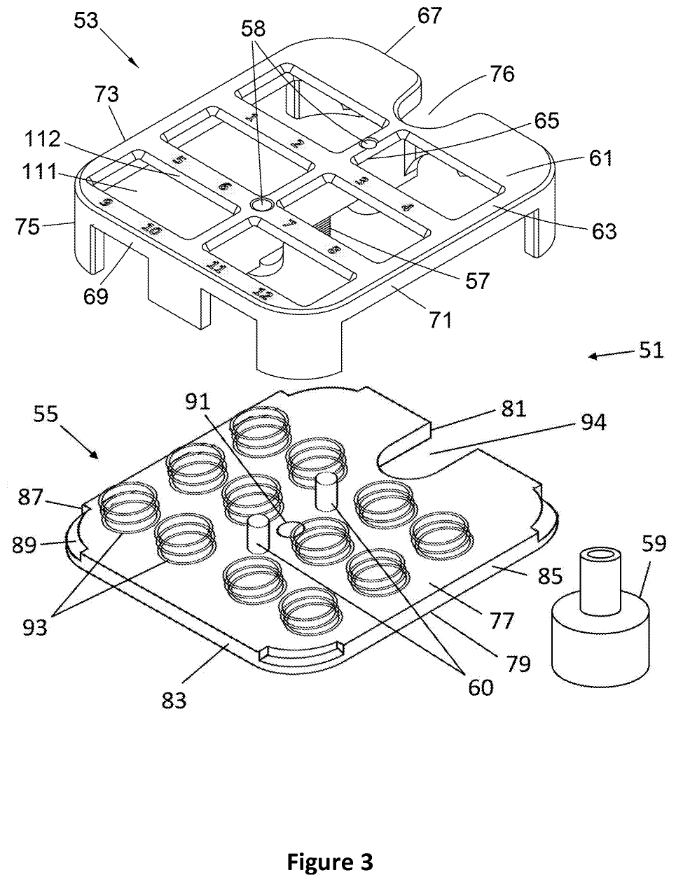

FIG. 3 is a perspective view of a puck holder according to a second aspect of the present invention in an unassembled form with the puck tray separated from the puck clamp;

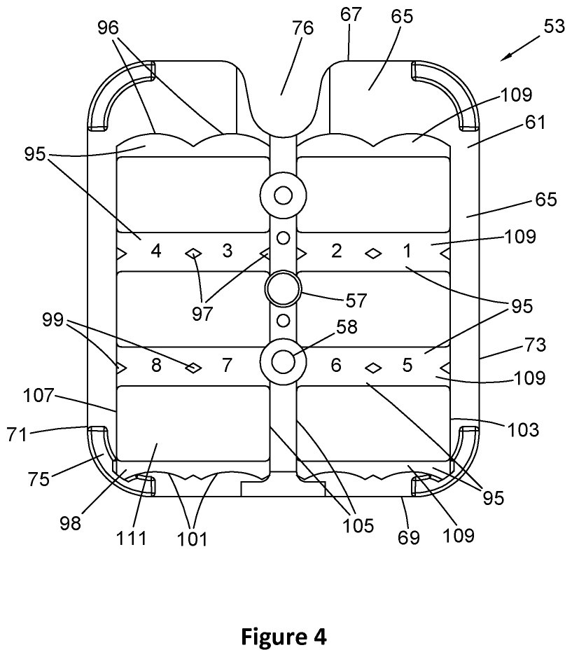

FIG. 4 is a plan view of the interior of the puck tray of FIG. 3;

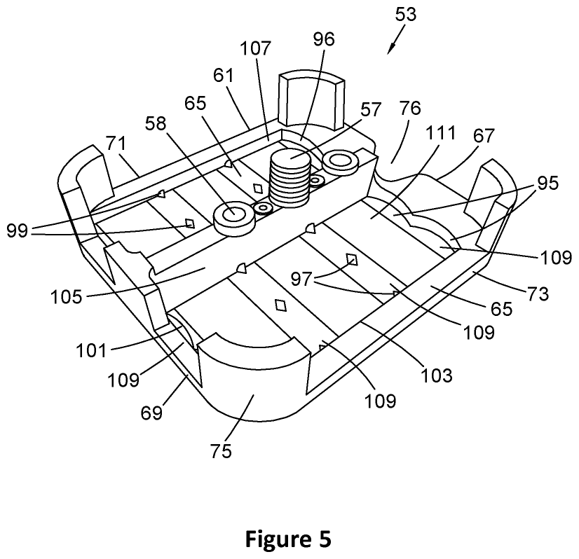

FIG. 5 is a perspective view of the interior of the puck tray of FIG. 3;

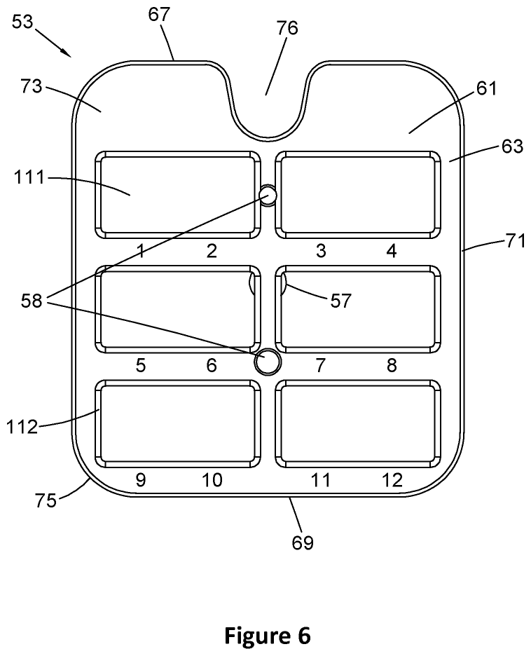

FIG. 6 is a plan view of the exterior of the puck tray of FIG. 3;

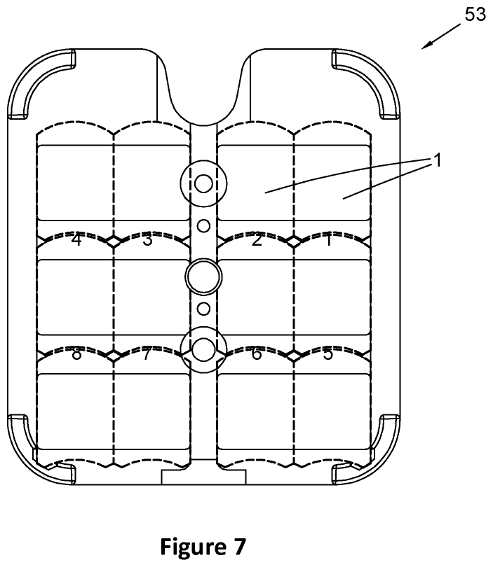

FIG. 7 is a plan view of the interior of the puck tray of FIG. 3 loaded with twelve pucks;

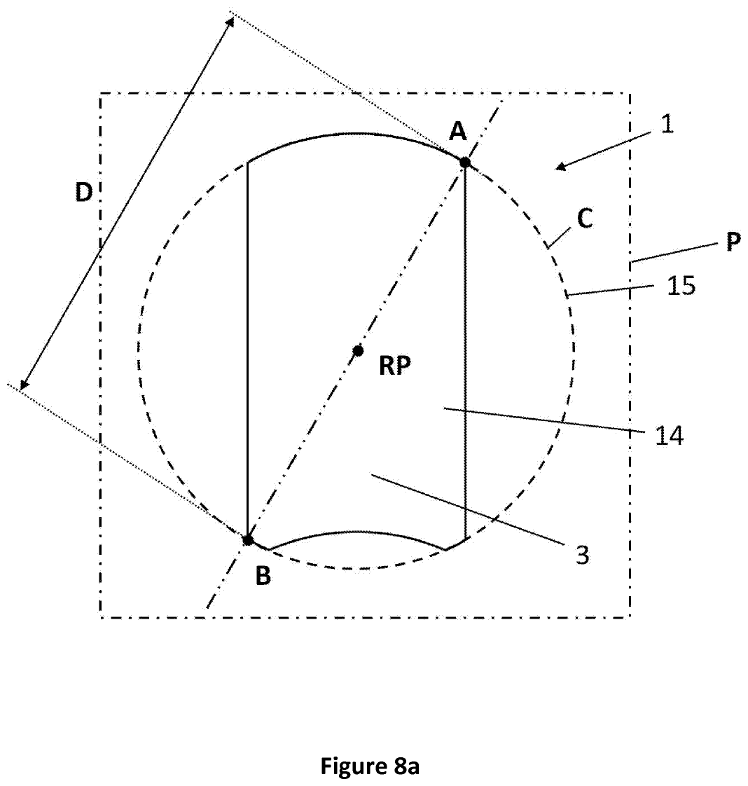

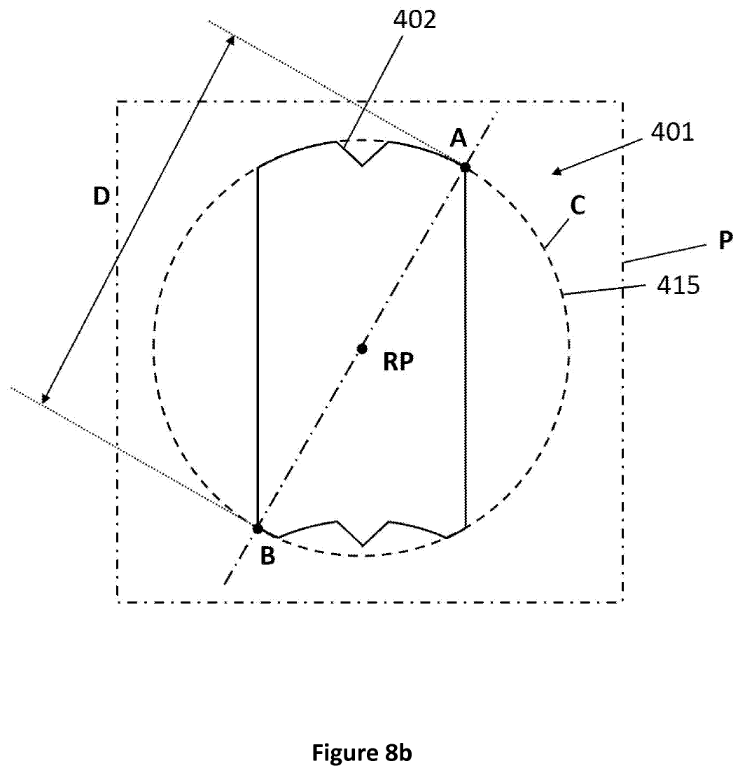

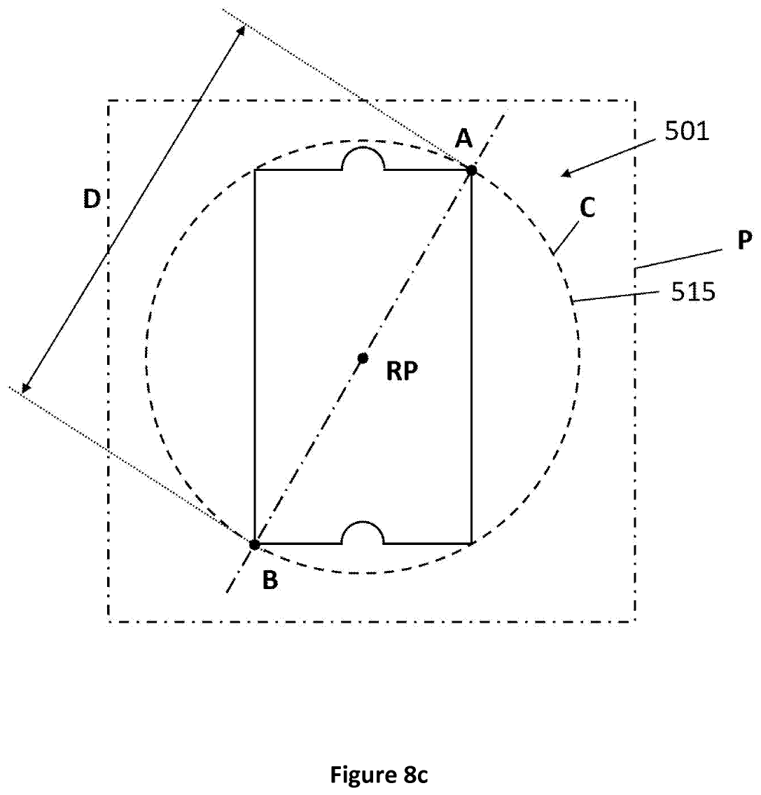

FIGS. 8a, 8b and 8c are plan views of alternative pucks according to the present invention;

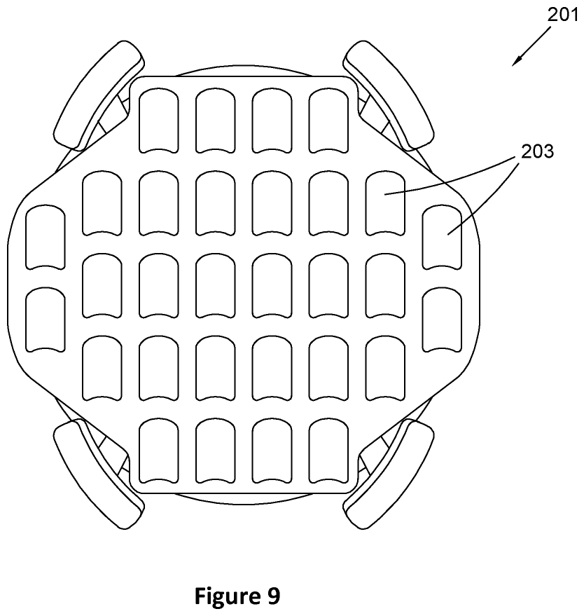

FIG. 9 is a plan view of a puck mould; and

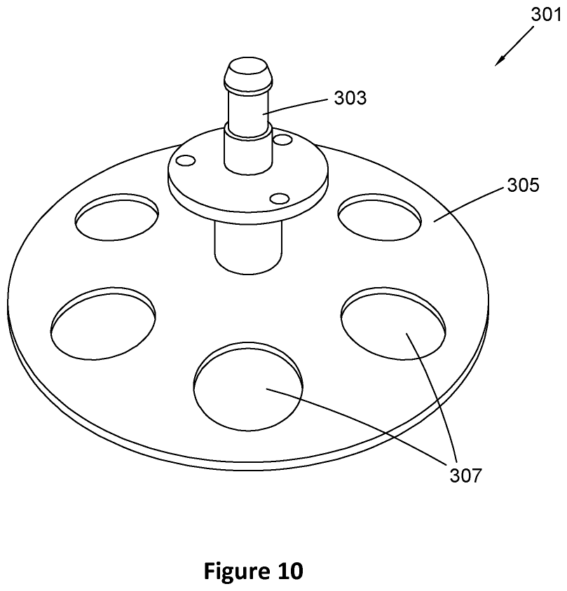

FIG. 10 is a perspective view of a puck polishing tool.

A one piece moulded puck 1 according to a first aspect of the present invention is shown in FIG. 1. The puck 1 has a material inspection surface 3 that is parallel to a clamping surface 5, a first side surface 7 that is parallel to a second side surface 9, a convex front orientation surface 11 and a partially concave rear orientation surface 13. The surfaces 3, 5, 7, 9, 11 and 13 defining a body (14).

FIG. 2 illustrates how the form of the forward orientation surface 11 and the form of part of the rearward orientation surface 13 are defined by the circumference of a first imaginary circle 15 that is drawn around the puck 1 and that is parallel to the plane of the material inspection surface 3. The forward orientation surface 11 is curved convexly around the circumference of the first imaginary circle 15. The rearward orientation surface 13 has a right hand outer corner surface 17 and a left hand corner surface 19, each of which corner surfaces 17,19 are curved convexly around the circumference of the circle 15. A central concave surface 21 is located between the corner surfaces 17,19 and has a radius of curvature that matches the radius of curvature of the forward orientation surface 11, as shown by a second imaginary circle 16. The first side surface 7 is formed along a chord that runs between the right hand end of the forward orientation surface 11 and the right hand end of the right hand corner surface 17. The second side surface 9 is formed along a chord that runs between the left hand end of the forward orientation surface 11 and the left hand end of the left hand corner surface 19.

The material inspection surface 3, the clamping surface 5, the first side surface 7 and the second side surface 9 are planar surfaces.

The forward orientation surface 11 is a curved surface. The rearward orientation surface 13 is made up of the right hand corner surface 17, the left hand corner surface 19 and the central concave surface 21, each of which of those three surfaces is a curved surface and each has the same radius of curvature.

The puck 1 has a height H between the material inspection surface 3 and the clamping surface 5 that is less than the length L of the puck 1 between the forward and rearward orientation surfaces 11 and 13. Typically, the height of the puck is between 10 mm and 15 mm, the width of the puck is between 14 and 18 mm and the length of the puck 1 is slightly less than 30 mm, which is the diameter of the first and second imaginary circles 15,16. The material surface 3 is one outer surface of a sample zone 23. The sample zone 23 is formed from rock drill cuttings 24 held together by a bonding resin 26 and extends halfway through the height of the puck 1 until it transitions into a resin zone 25 in which there are no drill cuttings 24.

A puck holder 51 according to a second aspect of the present invention is shown in FIG. 3. The puck holder comprises a generally rectangular puck tray 53, a generally rectangular puck clamping plate 55 and a clamping arrangement, which comprises a threaded stud 57, two cylindrical bores 58, a clamping wheel with a threaded bore 59 and two location pins 60, and which is used to clamp up to twelve pucks 1 between the puck clamping plate 55 and the puck tray 53.

The puck tray 53 has a window frame 61 that comprises an external top surface 63 and an internal bottom surface 65, which are generally parallel to each other, an external front side surface 67 and an external rear side surface 69 which are parallel with each other and an external right side surface 71 and an external left side surface 73 which are generally parallel with each other and perpendicular to the external front side surface 67 and external rear side surface 69. The upper and lower surfaces 63,65 have rounded corners and at each corner a support leg 75 extends perpendicularly from the lower surface 65. A tray location slot 76 is provided through the thickness of the external top surface 63 and extends perpendicularly from the front side surface 67, to provide a gap into which a complementary peg provided on a scanning electron microscope (not shown) can be located.

The puck clamping plate 55 has an upper surface 77 and a lower surface 79 which are generally parallel to each other, a front side surface 81 and a rear side surface 83 which are parallel to each other and a right side surface 85 and a left side surface 87 which are generally parallel with each other and perpendicular to the front side surface 81 and rear side surface 83. The upper and lower surfaces 77,79 have rounded corners and recessed support leg locators 89 are provided at each corner. The two location pins 60 of the clamping arrangement are spaced apart from each other and extend perpendicularly from the upper surface 77. A clamp hole 91 is located at the centre of the puck clamping plate 55, passes through the plate, and is situated between the two location pins 60. Twelve helically coiled clamping springs 93 are fixed to the upper surface 77 and extend perpendicularly from it. A plate location slot 94 is provided through the thickness of the puck clamping plate 55 and extends perpendicularly from the front side surface 81, to provide a gap into which a complementary peg provided on a scanning electron microscope (not shown) can be located. The plate location slot 94 and the tray location slot 76 are aligned when the puck clamping plate 55 and the puck tray 53 are clamped together.

FIG. 4 illustrates the internal bottom surface 65 of the puck tray 53, which is provided with twelve puck recesses 95 that extend part way through the thickness of the window frame 61 from the internal bottom surface 65. The puck recesses 95 are arranged in a regular array of four columns and three rows, when viewed from the front of the puck tray 53. The puck recesses 95 are numbered from one to twelve, with numbers one to four in the front row, i.e. the row nearest the front of the puck tray 53, starting from the right hand side (the right side in the following description is the right side when the puck tray 53 is viewed in plan view with the internal bottom surface 65 facing upwards), numbers five to eight in the middle row, starting from the right hand side and numbers nine to twelve in the rear row, starting from the right hand side. The puck recesses 95 in the first row have at their front end a curved profile 96 with a radius of curvature that matches the radius of curvature of the convex front orientation surface 11 of a puck 1. Each puck recess 95 in the front row is provided with a right hand triangular abutment 97 and a left hand triangular abutment 99 that are each complementary with the outer corner surfaces 17 and 19 of the puck 1. The puck recesses 95 in the middle row and the rear row have at their front end and at their rear end, right and left hand triangular abutments 97 and 99. The triangular abutment 97 at the right hand side of puck recess location nine and the triangular abutment 99 at the left hand side of puck recess location twelve are each integrated with one of the corner support legs 75 and the interior surface of the corner support leg 75 is provided with a cut-out 98 that extends for the height of the leg. The puck recesses 95 in the rear row also have at their rear end a curved retaining abutment 101 that has a radius of curvature that matches the radius of curvature of the central concave surface 21 of the puck 1.

The puck recesses 95 at locations one, five and nine are provided at their right hand side with an abutment surface provided by an outside restraining wall 103. A central restraining wall 105 provides an abutment surface at the left hand side of the puck recesses 95 at locations two, six and ten and an abutment surface at the right hand side of the puck recesses 95 at locations three, seven and eleven are provided. The puck recesses 95 at locations four, eight and twelve are provided at their right hand side with an outside restraining wall 107.

The curved profiles 96, the left and right hand triangular abutments 97,99 and the curved retaining abutments 101 extend perpendicularly from elongate bars 109 that, on the right hand side, extend across the puck tray 53 from the outside restraining wall 103 to the central restraining wall 105 and, on the left hand side, from the outside restraining wall 107 to the central restraining wall 105. Six elongate windows 111 are created between the elongate bars 109 and each window is aligned with two puck recesses 95, for example a first window 111 is aligned with puck recess locations one and two and a second window 111 is aligned with puck recess locations three and four.

The external top surface 63 of the puck tray 53 has internally chamfered surfaces 112 around each of the windows 111.

When it is desired to analyse a set of up to twelve pucks 1, the puck holder 51 is loaded with the pucks 1 so that they can be presented to a scanning electron microscope. This is as shown in FIG. 7, with the pucks 1 represented by dotted outlines. In order to load the puck tray 53, it is separated from the puck clamping plate 55 by rotation of the clamping wheel 59 about the threaded stud 57 so that the clamping arrangement is released. The puck tray 53 is placed on a surface with its interior side facing upwards. The twelve pucks 1 are loaded into the puck tray 53, with the material inspection surface 3 of each puck 1 facing towards the interior of the puck tray 53. The pucks 1 can be placed into the puck tray 53 in any order until all twelve pucks 1 are in the puck tray 53. The dimensions of the puck recesses 95 in the puck tray 53 are selected so that the pucks 1 are a tight clearance fit with each other and with the puck tray 53. This facilitates easy loading but prevents angular misalignment of the pucks 1 relative to the puck holder 51.

A puck 1 that is located in the middle row in the puck tray 53 engages with a puck 1 that is located in the front row and with a puck 1 that is located in the rear row. The convex front orientation surface 11 of the puck 1 in the middle row fits within the central concave surface 21 at the back of the puck 1 in the front row and the central concave surface 21 of the puck 1 in the middle row extends around the convex front orientation surface 11 of the puck 1 in the rear row. The first and second side surfaces 7,9 of each puck 1 engage either with a first or a second side surface 7,9 of an adjacent puck 1, or with the central restraining wall 105, or with one of the outside restraining walls 103, dependent upon the location of the puck 1 within the puck tray 53.

Once the puck tray 53 has been loaded with the set of up to twelve pucks 1, the clamping plate 55 is placed on top of the puck tray 53. The clamping wheel 59 is then located over the threaded stud 57 and the clamping wheel 59 is rotated to move the clamping plate 55 into contact with the puck tray 53. Rotation of the clamping wheel 59 is stopped when the support legs 75 of the puck tray 53 abut the support leg locators 89 of the clamping plate 55. The clamping springs 93 are placed in compression during the clamping operation and thus each clamping spring 93 exerts a force on a puck 1 that keeps that puck 1 in contact with the internal surface of the puck tray 53. The material inspection surface 3 of each puck 1 is then visible through one of the windows 111 in the puck tray 53.

The puck holder 51 with the set of up to twelve pucks 1 can then be placed in a scanning electron microscope for inspection. The puck holder 51 is oriented so that the tray location slot 76 and the plate location slot 94 are aligned with a peg in the scanning electron microscope (not shown).

Once inspection has been completed the puck holder 51 can be removed from the scanning electron microscope and the pucks 1 can be removed from it and stored, in case they need to be subjected to further inspection.

If one or more of the pucks 1 needs to be subjected to further inspection, then it can be retrieved from storage and placed back into the puck holder 51. The pucks 1 can only be placed back into the puck holder 51 in one orientation (assuming that the material inspection surface 3 is located adjacent to the internal bottom surface 65 of the puck tray 53) because of the convex front orientation surface 11 and the central concave surface 21 of the puck 1 and the shape of the puck recesses 95. This ensures that the further inspection of the puck 1 is undertaken on the desired portion of that puck 1.

FIGS. 8a, 8b and 8c show puck 1, puck 401 and puck 501 respectively. The pucks 1, 401 and 501 have different shapes but share the inventive features of the first aspect of the present invention.

In FIG. 8a, puck 1 is shown in plan view, parallel to a plane P. The first imaginary circle 15 within the plane P has a circumference C and a diameter D. The top right hand end of the convex front orientation surface 11 contacts the imaginary circle 15 at a first point, Point A, on its circumference C. The left hand end of the left hand outer corner surface 19 contacts the imaginary circle 15 at a second point, Point B, on the circumference C of the first imaginary circle 15. A line between Point A and Point B passes through the centre point of the imaginary circle 15 and thus the length of a line between Point A and Point B is equal to the diameter D of the imaginary circle 15. The centre point of the imaginary circle 15 forms a Rotation Point RP for the puck 1.

FIG. 8b shows a notched puck 401 in plan view, parallel to a plane P. A first imaginary circle 415 within the plane P has a circumference C and a diameter D. The top right hand end of a convex front orientation surface 411 contacts the imaginary circle 415 at a first point, Point A, on its circumference C. The left hand end of the left hand outer corner surface 419 contacts the imaginary circle 415 at a second point, Point B, on the circumference C of the first imaginary circle 415. A line between Point A and Point B passes through the centre point of the imaginary circle 415 and thus the length of a line between Point A and Point B is equal to the diameter D of the imaginary circle 415. The centre point of the imaginary circle 415 forms a Rotation Point RP for the puck 401. A v-shaped notch 402 is provided at the midpoint of the length of the convex front orientation surface 411. A v-shaped projection 404 is located at the midpoint of a central concave surface 421 of the notched puck 401. The v-shaped projection 404 is complementary in size and shape to the v-shaped notch 402 so that a v-shaped projection 404 is a close fit within a v-shaped notch 402.

FIG. 8c shows a generally rectangular puck 501 in plan view, parallel to a Plane P. A first imaginary circle 515 within the plane P has a circumference C and a diameter D. The puck 501 has a front orientation surface 511 aligned with one of the short sides of the rectangular puck 501 and a rear orientation surface 508 aligned within the other of the short sides of the rectangular puck 501. The right hand end of the front orientation surface 511 contacts the imaginary circle 515 at a first point, Point A, on its circumference C. The left hand end of the rear orientation surface 508 contacts the imaginary circle 515 at a second point, Point B, on the circumference C of the first imaginary circle 515. A line between Point A and Point B passes through the centre point of the imaginary circle 515 and thus the length of a line between Point A and Point B is equal to the diameter D of the imaginary circle 515. The centre point of the imaginary circle 515 forms a Rotation Point RP for the puck 501. A semi-circular projection 510 is located at the midpoint of the front orientation surface 511. A semi-circular notch 512 is located at the midpoint of the rear orientation surface 508. The semi-circular projection 510 is complementary in size and shape to the semi-circular notch 512 so that a semi-circular projection 510 is a close fit within a semi-circular notch 512.

A puck mould 201 is shown in FIG. 9. The mould 201 contains thirty puck recesses 203. To manufacture a set of pucks 1 a sample of rock drill cuttings 24 is placed into each puck recess 203 and bonding resin 26 is then poured into each recess 203. The puck mould 201 is then placed into an oven (not shown) and the bonding resin 26 is cured under pressure.

The pucks 1 can be polished with existing polishing machines and holders, such as the puck polishing tool 301 shown in FIG. 10. The puck polishing tool 301 comprises a spindle 303 that enables connection with a polishing machine (not shown) and a flat disc 305 that is attached to the spindle (303). The flat disc is provided with six circular puck holes 307 arranged at regular angular intervals. To polish a set of pucks 1, the puck polishing tool 301 is placed in the polishing machine, the puck polishing tool 301 is located over an abrasive medium, the pucks 1 are placed into the puck holes 307 and the abrasive medium is rotated relative to the pucks 1. The pucks 1 can rotate within the puck holes 307 during the polishing operation but the puck holes 307 are sized so that the pucks 1 are constrained from translation relating to the flat disc 305.

1. A sample block comprising a planar material inspection surface and a body extending away from the material inspection surface in a direction perpendicular to the planar material inspection surface, wherein the external perimeter of the sample block in a plane parallel to the material inspection surface is defined in part by a circle located within plane and that surrounds the sample block, wherein the external perimeter of the sample block extends to the circumference of the circle and touches it at a first contact point on the circle and wherein there is a second contact point on the circle that is diametrically opposite to the first contact point and wherein the external perimeter of the sample block extends to the circumference of the circle and touches it at the second contact point, the sample block comprising a first orientation feature forming part of the external perimeter of the sample block in the plane, the first orientation feature extending at least part way through the height of the body, wherein there is a rotation point on the sample block that is located midway along a line drawn between the first contact point and the second contact point (B) and wherein the sample block is asymmetrical when rotated in the plane about the rotation point.

2. A sample block as claimed in claim 1, further comprising a second orientation feature extending at least part way through the height of the body, wherein the first and second orientation features have complementary shapes, such that, in use, the second orientation feature of one of two sample blocks can be located at least partially within the first orientation feature of the other of the two sample blocks, or the first orientation feature of one of two sample blocks can be located at least partially within the second orientation feature of the other of the two sample blocks.

3. A sample block as claimed in claim 2, wherein the first and second orientation features are opposite each other.

4. A sample block as claimed in claim 2, wherein the body is defined by the material inspection surface, by a back surface that is perpendicularly spaced apart from the material inspection surface by a forward orientation surface comprising the first orientation feature and by a rearward orientation surface comprising the second orientation feature, wherein the forward and rearward orientation surfaces are located opposite each other.

5. A sample block as claimed in claim 4, further comprising a first side surface and a second side surface, wherein the first and second side surfaces are parallel to each other and are each connected at one end to the forward orientation surface and at the other end to the rearward orientation surface.

6. A sample block as claimed in claim 2, wherein the first orientation feature is a forward orientation surface which has a convex curved section with a radius of curvature that matches the radius of the circle, and wherein the second orientation feature is a rearward orientation surface, which has a concave curved section with a radius of curvature that matches the radius of the circle.

7. A sample block as claimed in claim 6, wherein, the concave curved section of the rearward orientation surface further comprises at each of its ends a corner surface and wherein the corner surfaces have a convex curve with a radius of curvature that matches the radius of the circle.

8. A sample block tray for use with sample blocks according to claim 1 having a surface that is provided with a plurality of sample block recesses wherein the sample block recesses are arranged in an array of rows and columns and wherein within a column each of the sample block recesses in that column is at least partially open to an adjacent sample block recess, wherein abutments are provided between rows of sample block recesses, wherein a window is associated with each of the sample block recesses, wherein the sample block recesses are arranged at least in a forward row and in a rearward row and in a first column and in a second column, wherein the sample block recesses in the forward row are provided at their forward end with a concave restraining wall that has a circular curvature and that is complementary to the orientation feature of a sample block and at their rearward end with an abutment at each corner and wherein the sample block recesses in the rearward row are provided at their forward end with an abutment at each corner and at their rearward end with a convex restraining wall that has a circular curvature.

9. A sample block tray having a surface that is provided with a plurality of sample block recesses wherein the sample block recesses are arranged in an array of rows and columns and wherein within a column each of the sample block recesses in that column is at least partially open to an adjacent sample block recess, wherein abutments are provided between rows of sample block recesses and wherein a window is associated with each of the sample block recesses.

10. A sample block tray as claimed in claim 9, wherein the sample block recesses are arranged at least in a forward row and in a rearward row and in a first column and in a second column, wherein the sample block recesses in the forward row are provided at their forward end with a concave restraining wall that has a circular curvature and at their rearward end with an abutment at each corner and wherein the sample block recesses in the rearward row are provided at their forward end with an abutment at each corner and at their rearward end with a convex restraining wall that has a circular curvature.
